(19) United States
(12) Patent Application Publication
(10) Pub. No.: US 2017/0059670 A1
(43) Pub. Date: Mar. 2, 2017

(54) METHOD AND DEVICE FOR DETERMINING A MAXIMUM CHANGE IN A MAGNETIC FIELD IN A MAGNETIC RESONANCE IMAGING SCANNER

(71) Applicants: Matthias Gebhardt, Erlangen (DE); Gudrun Ruyters, Erlangen (DE)

(72) Inventors: Matthias Gebhardt, Erlangen (DE); Gudrun Ruyters, Erlangen (DE)

(21) Appl. No.: 15/245,398

(22) Filed: Aug. 24, 2016

(30) Foreign Application Priority Data
Aug. 26, 2015 (DE) 102015216323.7

(51) Int. Cl. G01R 33/24; G01R 33/54; G01R 33/28

(52) U.S. Cl. CPC G01R 33/24; G01R 33/288; G01R 33/543

(57) ABSTRACT

A method and system for determining a maximum function for a magnetic resonance imaging scanner. The maximum function indicates the upper bound of a magnetic field magnitude in an examination volume in dependence on activation signals of magnetic coils acting on the examination volume. The examination volume is divided into a plurality of partial volumes. The method determines matrices (M_{B}), which, when multiplied by a vector of the activation signals of the magnetic coils, indicate a resultant square of the magnetic field magnitude for each partial volume.

### CROSS REFERENCE TO RELATED APPLICATIONS

This application claims the benefit of DE 10 2015 216 323.7, filed on Aug. 26, 2015, which is hereby incorporated by reference in its entirety.

### TECHNICAL FIELD

Embodiments relate to a method for determining a maximum rate of change in a magnetic field for a magnetic resonance imaging scanner. The maximum rate of change in a magnetic field determined indicates an upper bound of a rate of change in a magnetic field in an examination volume in dependence on activation signals of magnetic coils acting on the examination volume.

### BACKGROUND

Magnetic resonance imaging scanners are imaging devices that to depict an object under examination align nuclear spins in the object under examination with a strong external magnetic field and excite them by a magnetic alternating field to precession about this alignment. The precession or return of the spins from this excited state into a low energy state in turn generates a response in the form of a magnetic alternating field that is received by antennas.

Magnetic gradient fields are used to impart spatial encoding to the signals that subsequently enables the assignment of the received signal to a volume element. The received signal is then evaluated and a three-dimensional imaging display of the object under examination is provided.

According to the law of induction, time varying magnetic fields generate a voltage in electrical conductors that increases with the rate of change. Strong magnetic fields in conjunction with rapid changes may result in the generation of voltages that may be hazardous in a variety of ways. There are implanted electric devices, such as, for example pacemakers, cochlea implants as hearing aids or even drug pumps or dosing devices that may not be removed during an examination and the malfunction of which may endanger the health or life of the patient. These devices have electric components that may be destroyed or at least experience functional impairment due to induced voltages. A further complicating factor is that, unlike electric fields, magnetic fields may not be completely screened by a metal sheath. In addition, imaging would be no longer possible or would at least be greatly impaired in a region that is screened to a greater or less degree. Further, voltages may be induced on metallic implants in teeth or joints and result in undesirable movements or sensations of pain.

### SUMMARY AND DESCRIPTION

The scope of the present invention is defined solely by the appended claims and is not affected to any degree by the statements within this summary. The present embodiments may obviate one or more of the drawbacks or limitations in the related art.

The object of the embodiments is to avoid danger to patients, for example, patients with implants, from a magnetic resonance imaging scanner due to rapidly changing magnetic fields.

In an embodiment, a maximum function is determined for a magnetic resonance imaging scanner. The maximum function indicates an upper bound of a magnetic field magnitude in an examination volume V in dependence on a plurality of activation signals I from magnetic coils acting on the examination volume. There are three different activation signals that correspond to the three partial gradient coils required for three-dimensional spatial resolution. Since the relationship between activation signals and magnetic field magnitude is temporally invariant, simple derivation of the activation signals according to time enables the derivation of a change to the magnetic field magnitude per time unit. The examination volume V is divided into a plurality of partial volumes Vᵢ so that the partial volumes Vᵢ completely cover the examination volume V and may not overlap or may only partially overlap.

An embodiment includes an act of specifying first matrices M_{B} that, when multiplied by a vector I formed from the activation signals of the plurality of magnetic coils, indicate a resultant magnetic field magnitude |B|²=I^{T}*M_{B}*I for each partial volume Vᵢ. In this context, the vector I^{T} is the transposed vector of vector I. The matrix may be determined by the integration of a coil current along the coils according to the Biot-Savart law:

$$d \vec{B} = \frac{{μ}_{0}}{4 π} \cdot I \cdot \frac{d \vec{l} \times \hat{r}}{{r}^{2}} , \qquad Equation 1$$

The integral may be determined analytically in exceptional cases, but may also be determined by numerical integration.

In a further act, all partial volumes Vᵢ are grouped into a plurality of groups so that, for a subscript index j of each first group of the plurality of groups, the difference between the matrix M_{Bj} and the matrix M_{B1} of any other element V₁ of the first group is epsilon positive semidefinite. The difference between matrices is obtained in each case by subtracting the corresponding matrix elements.

Epsilon positive semidefinite is a matrix difference (M_{B1}−M_{Bj}) for a given positive value ε when all eigenvalues of the difference matrix (M_{B1}−M_{Bj}) are ≧−ε. For example, the matrix (M_{B1}−M_{Bj} ε*E) is positive semidefinite, wherein the matrix E is the unit matrix with the same dimensions as M_{Bj}. Another suitable positive definite matrix instead of the unit matrix may be used. When the limit value ε approaches zero, the matrix (M_{B1}−M_{Bj}) has the property of being positive semidefinite.

The maximum function of the magnetic field magnitude |B| is specified by the maximum of the square root of I*^{T}*M_{Bj}*I of all groups plus an addition dependent on ε.

Due to the different independently activated simultaneous operation of the different field coils, a few ad hoc identifiable partial volumes are not sufficient to determine the maximum throughout the entire volume. However, the determination of the maximum on the basis of all partial volumes is numerically very complicated. The object is to reduce the monitoring of the entire volume to comparatively few numerical acts during the actual monitoring by suitable preparatory acts.

Due to the epsilon positive semi definiteness of the difference matrix (M_{Bj}−M_{B1}), the greatest possible magnetic field magnitude for the partial volumes of the group is obtained with a magnetic field magnitude determined for the matrix M_{Bj} plus an added margin dependent on ε for all activation signals. It is no longer necessary to determine the magnetic field magnitude for all partial volumes in a group and then select the maximum as it has been analytically proven that the value within the group for the maximum partial volume Vⱼ and the associated matrix M_{Bj} is the maximum value. It is then only necessary to determine the maxima for the individual groups using the maximum partial volumes and to establish the highest value therefrom in order to obtain an upper bound for the magnetic field magnitude. Since the number of maximum partial volume or groups is one or more degrees of magnitude below the total number of partial volumes, it is also possible to determine the maximum magnetic field magnitude in the examination volume in real time. It is then advantageously also possible to carry out real time monitoring and to interrupt the measurement if limit values are exceeded.

In this context it is also conceivable to replace the epsilon positive definite condition by the more precise condition ‘positive semidefinite’ for the matrix difference. This reduces the epsilon dependent added safety margin to the maximum rate of change in a magnetic field to a minimum.

However, the epsilon positive semidefinite condition advantageously provides that the magnitudes of the magnetic fields plus an added margin for the partial volume Vⱼ that is dependent upon the bound ε are greater for all activation signals I than those for the volume V₁. Hence, a calculation of the magnetic field magnitude for the volume Vⱼ provides the maximum value for the respective group. Under the epsilon positive semidefinite condition, the value ε for the difference matrices may be used to shift the maximum value that may not be exceeded upward in dependence on □, wherein simultaneously there may be an increase in the number of matrices M_{B1} whose differences from M_{Bj} are epsilon positive semidefinite. Thus, this advantageously enables the number of groups, and hence also the time required for checking in real time, to be reduced, wherein in exchange the activation signals have to be reduced by the deduction of a safety margin dependent on ε.

Since the magnetic field B0 of a superconducting coil may be static and independent of the activation signals of the other magnetic coils, for example the gradient coils, this may be ignored. However, it is in principle also conceivable, to take into account other dynamically driven magnetic coils in addition to the gradient coils.

The magnetic resonance imaging scanner includes a control system designed to determine a maximum change in a magnetic field in that a maximum value for the temporal derivative of the square root from I^{T}*M_{Bj}*I is determined for all subscript index indices j of the maximum partial volumes Vⱼ. In this context, the matrices M_{Bj} are determined.

Due to the advantageous low number of maximum partial volumes, the magnetic resonance imaging scanner is able to use the control system to determine the magnetic field magnitudes or the change therein in real time from the change in the activation signals d|B|/dt=d(I^{T}*M_{Bj}*I)^{1/2}/dt=(dI^{T}/dt*M_{Bj}*dI/dt)^{1/2}. This may enable the observance of limit values. In this context, it is of particular advantage for the observance also to be demonstrated in an analytical manner, which is of particular significance in statutory approval proceedings. In the event of a possible disclosure obligation, it is then also possible to demonstrate whether a device is utilizing maximum partial volumes and matrices determined by the method described herein.

In an embodiment, the acts of the method are executed by a computer.

The execution of the method on a computer accelerates and facilitates the execution of the method. In addition, automated execution also enables the execution of the method with different start parameters, such as, for example, the selection of the partial volumes, and hence the further optimization of the result, for example with respect to the number of groups obtained.

In one embodiment, the computer subdivides the examination volume V into partial volumes Vᵢ. In this context, it is also conceivable for the computer to subdivide the examination volume in dependence on input parameters such as, for example, partial volume size, number of partial volumes, symmetries or the like.

The subdivision of the examination volume by the computer is a simple way of providing the complete division of the examination volume into partial volumes. This act is advantageously (but not necessarily) performed only once for a given coil system.

In one embodiment, in a further act, a maximum temporal change in the magnetic field magnitude in a partial volume is determined. This is for example achieved in that the first matrix (M_{Bj}) is multiplied by a first derivative with respect to time of the vector (I) or the transposed vector (I^{T}) of the activation signals. The temporal derivative of the activation signals of the magnetic coils is formed by the temporal derivative of the individual activation signals.

According to the law of induction, the induced electric field is proportional to the change in a magnetic field. When the maximum temporal change in the magnetic field magnitude is determined, advantageously an upper bound is also determined for an induced electric field or an induced voltage applied to a conductor that is the decisive factor for an unwanted effect in the body.

In one embodiment, in the act of the grouping of all partial volumes (Vᵢ) into a plurality of groups, in each case an initial partial volume (Vⱼ) that has not yet been assigned to a group is selected and allocated to a new second group. All further partial volumes (V₁) that have not yet been allocated to a group are then checked as to whether the difference between the matrix M_{Bj} and the matrix M_{B1} is epsilon positive semidefinite with respect to a bound (e).

The checked partial volumes (V₁) that have not yet been assigned to a group are allocated to the second group when the difference between the matrix M_{Bj} and the matrix M_{B1} is epsilon positive semidefinite. The resultant second group is then a first group as described herein.

Advantageously, the epsilon positive semidefinite condition provides that the magnitudes of magnetic fields plus an additional margin dependent upon the bound ε for the partial volume Vⱼ are greater for all activation signals I than for the volume V₁. Hence, a calculation of the magnetic field magnitude for the volume Vⱼ provides the maximum value for the respective group. Under the epsilon positive semidefinite condition, the value □ for the difference matrices may be used to shift the maximum value that may not be exceeded upward in dependence on ε, wherein simultaneously there may be an increase in the number of matrices M_{B1} whose differences from M_{Bj} are epsilon positive semidefinite. This advantageously enables the number of groups and hence also the number of values to be calculated in real time to be reduced in that the upper bound is restricted and increased to a predefined degree.

In one embodiment, the partial volume is selected as the initial partial volume Vⱼ the matrix M_{Bj} of which has highest eigenvalue.

Advantageously, a large number of differences from the matrices M_{B1} is positive semidefinite or epsilon positive semidefinite for the matrix M_{Bj} with the highest eigenvalue.

In one embodiment, the bound ε is derived from the highest eigenvalue for the initial partial volume Vⱼ. The bound may be made dependent upon a magnitude of the eigenvalue. In a simple form, a proportionality factor is conceivable as a dependence.

The matrix with the highest eigenvalue has the property that, even when □ is selected as small, as many other matrix differences (M_{B1}−M_{Bj}) as possible are epsilon positive semidefinite. This enables a smaller upper bound to be achieved for the magnetic field magnitude or, with the same value, larger activation signals to be used so that stronger gradient fields are possible and nevertheless the upper bound for the magnetic field magnitude or the temporal derivative thereof is not exceeded.

In one embodiment, in the act of the grouping of all partial volumes Vᵢ into a plurality of groups, an initial partial volume Vⱼ is selected in a third group. In this context, the third group may, for example, be a predetermined group or a group created during the division of the examination volume into partial volumes. However, it is also conceivable for the third group to be the amount or a partial amount of the partial volumes that have not yet been assigned to a group.

In this context, all further partial volumes V₁ of the third group are checked as to whether the difference between the matrix M_{Bj} and the matrix M_{B1} is epsilon positive semidefinite with respect to a bound ε. The checked partial volume V₁ becomes the new initial partial volume Vⱼ of the third group when the difference between the matrix M_{Bj} and the matrix M_{B1} is not epsilon positive semidefinite. The checking of the epsilon positive semidefinite property is continued for all remaining partial volumes V₁ of third group with the new initial partial volume Vⱼ. In this context, it is advantageous also for M_{Bj}≧M_{B1} to result from the relationship M_{Bk}≧M_{B1} and M_{Bj}≧M_{Bk} (here, “≧” symbolizes that the difference between the matrices is epsilon positive semidefinite or positive semidefinite). The resultant third group is then a first group as described herein.

Hence, it is advantageously possible to enlarge the size of the third group in that the remaining elements are not divided into other groups when the epsilon positive semidefinite condition is not satisfied for a difference. It is also possible, for example, for geometric considerations, for groups to be predefined.

In one embodiment, the computer determines the matrix M_{Bj} to be determined for the second groups or third groups on the basis of the matrix M_{Bj} specified for the respective initial partial volume Vⱼ.

This advantageously enables a simplified determination of the matrices M_{Bj} for the individual groups.

In one embodiment, the matrix M_{Bj} is dependent upon a weighting factor W specified to the computer by a user for a partial volume.

Thus, it is advantageously possible for physically identical magnetic field magnitudes or the temporal derivatives thereof, to take account of different effects that may be spatially dependent. It is, for example, conceivable that the nerve tissue is more sensitive to induced voltages than fatty tissue so that a corresponding factor W in would have to be specified higher in region of the vertebral column than in the abdominal region.

In one embodiment, a user specifies a grouping criterion to the computer, wherein the computer groups the partial volume of the examination volume into groups in dependence on the grouping criterion.

In this way, it is, for example, possible to take account of specific physical circumstances such as symmetries or also the arrangement of the gradient coils and specify them to the method that may result in a more rapid outcome or even a better optimization result, such as a smaller number of groups and maximum partial volumes.

In one embodiment, the bound ε is small or zero. The value for ε may be selected small so that the margin added to the maximum rate of change determined by the maximum partial volumes in a magnetic field is only small, e.g., only 20%, 10%, 5% or 1% of the maximum rate of change in the magnetic field. In order to achieve small margins, it is conceivable for ε to adopt a small value, example 20%, 10%, 5% or 1% of the maximum eigenvalue of all matrices for all partial volumes or.

When ε is equal to zero, the epsilon positive semidefinite condition changes to the positive semidefinite condition. The difference matrix is precisely positive semidefinite when all eigenvalues are greater than or equal to zero. In this case, a change to the magnitude of the magnetic field determined for the partial volume Vⱼ indicates the maximum for the respective group directly and without any added safety margin so that advantageously the gradient field may have a strength up to this limit. Accordingly, in the case of small D values, the added margin may be correspondingly small.

### BRIEF DESCRIPTION OF THE DRAWINGS

The above described properties, features and advantages and the manner in which these are achieved will become clearer and more plainly comprehensible in conjunction with the following description of the exemplary embodiments described in more detail in conjunction with the drawings, which show:

FIG. 1 depicts an exemplary schematic of a magnetic resonance imaging scanner according to an embodiment;

FIG. 2 depicts a schematic of an examination volume and of the partial volumes thereof in cross section;

FIG. 3 depicts an example of gradient coils with simplified geometry for the calculation of matrices for the determination of the magnetic field;

FIG. 4 depicts a schematic flow diagram of an embodiment.

### DETAILED DESCRIPTION

The magnet unit 10 includes a field magnet 11 that generates a static magnetic field B0 for the alignment of nuclear spins in specimens or patients 40 in an examination volume. The examination volume is arranged in a leadthrough 16 extending in a longitudinal direction 2 through the magnet unit 10. The field magnet 11 is may be a superconducting magnet that is able to provide magnetic fields with a magnetic flow density of up to 3T or even more with the most recent devices. However, it is also possible to use permanent magnets or electromagnets with normally conducting coils for lower field strengths.

The magnet unit 10 further includes gradient coils 12 designed, for the spatial differentiation of the image region in the examination volume, to superimpose the magnetic field B0 with variable magnetic fields in three spatial directions. The gradient coils 12 may be coils made of normally conducting wires able to generate fields that are orthogonal to one another in the examination volume.

The magnet unit 10 also includes a body coil 14 designed to emit a radio frequency signal supplied via a signal line into the examination volume and to receive resonance signals emitted by the patient 40 and emit them via the signal line. However, for the emission of the radio frequency signal and/or the reception, the body coil 14 may be replaced by local coils 15 arranged in the leadthrough 16 close to the patient 40. However, it is also conceivable for the local coil 15 to be designed for transmission and reception and therefore for a body coil 14 to be dispensed with.

A control unit 20 supplies the magnet unit 10 with the different signals for the gradient coils 12 and the body coil 14 or the local coils 15 and evaluates the received signals.

Hence, the control unit 20 includes a gradient activation system 21 designed to supply the gradient coils 12 via leads with variable currents that provide the desired gradient fields in the examination volume in temporal coordination.

The control unit 20 also includes a radio frequency unit 22 designed to generate a radio frequency pulse with a prespecified temporal course, amplitude and spectral power distribution to excite a magnetic resonance of the nuclear spins in the patient 40. This enables a pulse power in the kilowatt range to be achieved.

The radio frequency unit 22 is also designed to evaluate the amplitude and phase of radio frequency signals received from the body coil 14 or a local coil 15 and supplied via a signal line 33 of the radio frequency unit 22. This, for example entails radio frequency signals that emit nuclear spins in the patient 40 in response to excitation by a radio frequency pulse in the magnetic field B0 or in a resultant magnetic field from a superimposition of B0 and gradient fields.

The control unit 20 also includes a control system 23 designed to provide temporal coordination of the activities of the gradient activation system 21 and the radio frequency unit 22. To this end, the control system 23 is connected to and exchanges signals with the other units 21, 22 by a signal bus 25. The control system 23 is designed to receive and process signals from the patient 40 that have been evaluated by the radio frequency unit 22 or to specify pulse shapes and signal shapes to the gradient activation system 22 and the RF pulse generating unit 23 and coordinate them temporally.

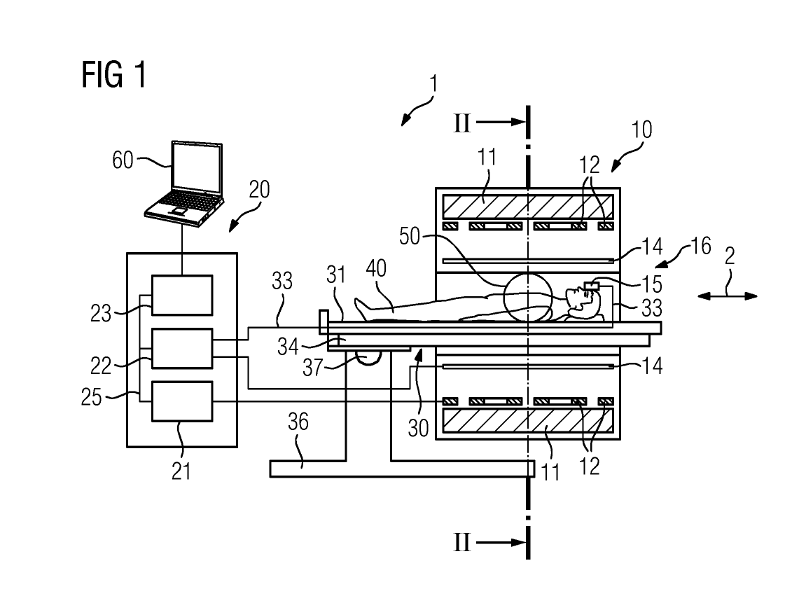

The patient 40 is arranged on a patient bench 30. Such patient benches 30 are already known from the field of magnetic resonance scanning. The patient bench 30 includes a first support 36 arranged under a first end 31 of the patient bench 30. To provide that the support 36 may maintain the patient bench 30 in a horizontal position, it may include a foot extending along the patient bench 30. To move the patient bench 30, the foot may also move using, for example, rollers. Apart from the support 36 at the first end 31, no structural elements are arranged between the ground and the patient bench so that the patient bench may be introduced to the first end 31 in the leadthrough 16 of the field magnet 11. FIG. 1 depicts linear track systems 34 connecting the support 36 in a movable manner to the patient bench 30 so that the patient bench is able to travel along the longitudinal direction 2. To this end, the linear track system includes a drive 37 enabling the patient bench 30 to be moved in a longitudinal direction 2 under the control of an operator or even the control system 23 such that it is also possible to examine regions of the patient's body with a greater extension than examination volume in the leadthrough 16.

The gradient activation system 21 generates activation signals for the gradient coils 12. Hence, the gradient activation system 21 contains information necessary to determine maximum magnetic field magnitudes or maximum values for temporal changes by the activation signals and the maximum function of the magnitude determined according to claim 1. To this end, the maximum functions determined are stored in the gradient activation system 21, the control system 23 or a separate computing unit or may be retrieved therefrom via a signal link, for example a network connection.

In this context, in one conceivable embodiment, the gradient activation system 21 is designed to limit the currents in the gradient coils 12 or the rate of change therein such that predetermined maximum values are not exceeded. It is also conceivable for the gradient activation system 21 to interrupt an image acquisition measurement in this case. If the determination of the maximum values is performed in the control system 23 or another unit, this may instruct the gradient activation system 21 via a signal link, for example the signal bus 25, to limit the gradient current or the rate of change therein or to interrupt the current supply to the gradient coils 12 or shut it down with a predetermined temporal rate of change.

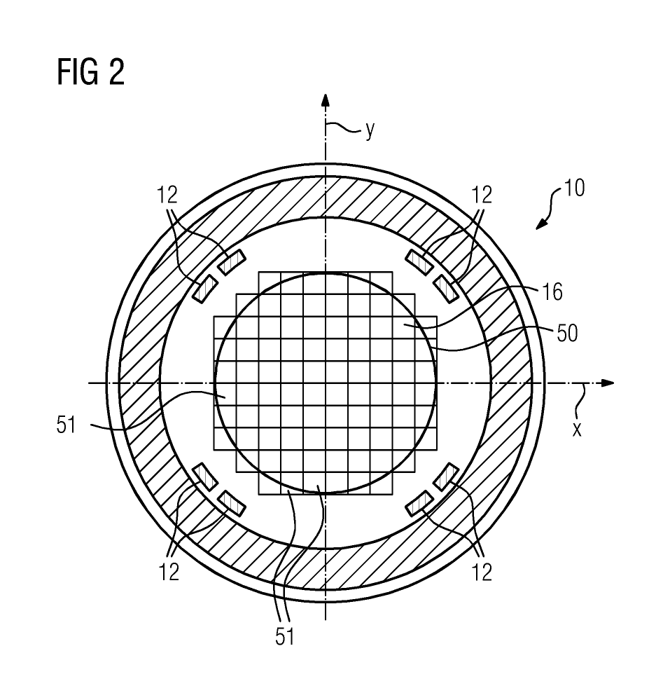

FIG. 2 is an exemplary symbolic depiction of an examination volume 50 and the partial volumes thereof 51. The depiction in FIG. 2 illustrates a cross section through the magnet unit 10 along the line II-II in FIG. 1. Magnetic resonance images may only be taken in a partial region of the leadthrough 16 with sufficient homogeneity of the static magnetic field and sufficient linearity of the gradient fields. However, the examination volume 50 is described as the volume in the leadthrough in which the patient 40 may be accommodated and which is located in the field of action of the gradient coils 12 such that potentially dangerously strong magnetic fields of the gradient coils 12 are able to act on the patient 40. However, for purposes of simplicity, it is also possible for the entire leadthrough 16 to be treated as an examination volume 50.

FIG. 4 is schematic depiction of a flow diagram.

In act S10, the examination volume 50 is divided into partial volumes 51 so that the entire examination volume 50 is covered by the partial volumes 51 without any gaps, e.g., no volume element of the examination volume 50 is not at least part of a partial volume 51. In this context, it is conceivable for the partial volumes 51 to overlap partially or even to divide the examination volume 50 without overlapping.

As shown in FIG. 2, partial volumes 51 in the form of cuboids or prisms are arranged along x, y and z-axes of a Cartesian coordinate system. However, rotationally symmetrical, spherically symmetrical or other coordinate systems are also conceivable. In this context, the coordinate system may be selected in dependence on the symmetry of the gradient coils 12.

The size of the partial volumes 51 is also dependent on the dimensions of the gradient coils and the distance of the respective partial volumes 51 from the gradient coils 12 since these indicate the degree to which the magnetic field may vary spatially and how narrow the network of the partial volumes 51 has to be drawn in order to acquire local field maxima. In this context, the dimensions of the individual partial volumes 51 may also vary in dependence on the location of the respective partial volume 51. For example, partial volumes 51 at a large distance from the gradient coils 12 may be selected larger. The spatial extension in the x, y and/or z axis may, for example, be 2 cm, 1 cm, 0.5 cm or 0.1 cm.

The division of the examination volume 50 may be performed automatically by a computer 60, manually, for example based on considerations relating to the coil geometry, or provided to the method as a file with the partial volumes 51. In the following, the partial volumes 51 are indicated in formulas by the symbol and subscript index Vᵢ.

In the method, in a further act S20, first matrices (M_{B}) are determined, which, when multiplied by a vector (I) formed from the activation signals of the gradient coils 12, indicate a resultant square of the magnetic field magnitude |B|²=I^{T}*M_{B}*I for each partial volume (Vᵢ) with the transposed vector (I^{T}) of vector (I). In the case of two coils L_{A} and L_{B} with the activation currents I_{A} and I_{B}, the vector I=(I_{A},I_{B}) is obtained for the activation signals.

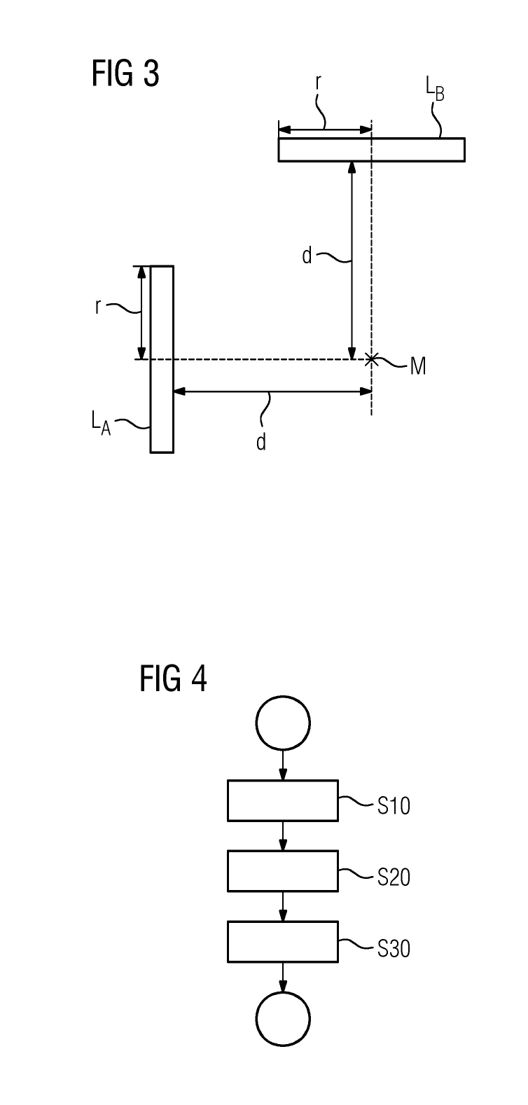

FIG. 3 depicts a simplified geometry with two identical, circular flat coils L_{A} and L_{B} with the number of windings N as gradient coils 12. The two coils L_{A} and L_{B} are arranged with respect to one another such that the surface normals of the coils L_{A} and L_{B} meet in a point M, which is at the same distance d from the two coils L_{A} and L_{B}.

According to the Biot-Savart law, the magnetic field strength at a point may be as follows:

$$d \vec{B} = \frac{{μ}_{0}}{4 π} \cdot I \cdot \frac{d \vec{l} \times \hat{r}}{{r}^{2}} , \qquad Equation 2$$

For an annular coil, this produces the following value for the magnetic field magnitude for the point M:

$$B = \frac{{NIr}^{2}}{2 {( {d}^{2} + {r}^{2} )}^{\frac{3}{2}}} \qquad Equation 3$$

The matrix for the point M in FIG. 3 is then obtained as

$$M = \begin{matrix}\frac{{Nr}^{2}}{2 {( {d}^{2} + {r}^{2} )}^{\frac{3}{2}}} & 0 \\ 0 & \frac{{Nr}^{2}}{2 {( {d}^{2} + {r}^{2} )}^{\frac{3}{2}}}\end{matrix} \qquad Equation 4$$

Equation 4 enables the matrix with the property |B|²=I^{T}*M_{B}*I to be determined for the point M for the simplified geometry in FIG. 3. For more complex geometries, integration according to the Biot-Savart law may be performed numerically. The integration has to be performed on a computer 60. Due to the special arrangement, in Equation 4, the non-diagonal elements of M are equal to zero, which may not generally be the case. However, the actual matrix is independent of the activation signals; the matrix for each point only has to be calculated once independently of the respective activation signals. It may be sufficient for the matrix determined by the activation signal may be multiplied during a later determination.

The temporal change in the magnetic field magnitudes may be determined in that the activation signals (I) are derived with respect to time and multiplied by the matrix (M) since the matrix elements are temporally invariant and, on the derivation of the transfer function with respect to time, are only present as constants before the time dependent terms of the activation signal.

In act S30, all the partial volumes (Vᵢ) are grouped into a plurality of groups. The grouping criterion is the condition that, for all partial volumes of a group, one partial volume Vⱼ is highlighted and the difference between the matrix M_{Bj} and the matrix M_{B1} of each other element V₁ of the first group is epsilon positive semidefinite. In this context, the subscript index j indicates a maximum partial volume for the respective group.

To differentiate between the two methods and the groups of partial volumes described therein, the groups are designated second or third groups depending upon the embodiment. Both methods have the same result that, for the maximum partial volume of each group, the above described semi definiteness is applicable with respect to the other elements of the respective group. The second groups and the third groups may also be first groups.

In one embodiment, act S30 starts with a partial volume Vⱼ being identified as a starting volume for a second group. In this embodiment, geometric considerations may play a role. For example, partial volumes may be suitable that in are the vicinity of a coil or in regions of a field maximum of the coil but are simultaneously spaced apart from the other coils or are located in regions of smaller fields of the other coils. A preselection of may be specified by a computer 60 carrying out the method or determined by the computer.

In an embodiment, eigenvalues are determined for the individual matrices M_{Bi}. Corresponding mathematical and numerical methods are known for such a procedure. In this context, the partial volume or volumes Vⱼ with the highest eigenvalues (e.g., the magnitudes of the eigenvalues) serve as the starting volume or volumes.

For the starting volume Vⱼ, the difference between the matrix M_{Bj} and the matrix M_{B1} of another volume V₁ that has not yet been allocated to a group is formed and checked as to whether the difference matrix is positive semidefinite. The difference matrix is positive semidefinite when all eigenvalues are greater than or equal to zero; therefore, the eigenvalues of the difference matrix should be determined and checked as to whether they are positive—this may be done with known numerical or analytical methods. A magnetic field magnitude for the starting volume Vⱼ for any activation signals is greater than for the other elements of the group. Therefore, the starting volume Vⱼ is the maximum partial volume of the second group.

If the difference matrix is positive semidefinite, the partial volume V₁ is assigned to the second group and a new partial volume V₁ sought for which the difference matrix is again formed with the starting volume Vⱼ and checked for the property “positive semidefinite”. The partial volume V₁ may be selected arbitrarily using a random method or, for geometric considerations, an algorithm provided for the selection, for example so that the partial volume is adjacent, or contrary to this, is also as far away as possible.

However, if the difference matrix is not positive semidefinite the grouping of the respective second group is completed. The partial volume V₁ becomes the starting volume Vⱼ for a further group, which is simultaneously a new second group and the process is repeated with the remaining partial volumes that have not yet been allocated to a group until once again for a subscript index 1 the condition that the difference matrix is positive semidefinite is no longer fulfilled and a new group is created. The iterative method is finally terminated when there are no further partial volumes that have not yet been assigned to a group. The last partial volume may also form its own second group with only one partial volume as an element.

In another embodiment, the partial volumes in act S30 are first divided into groups designated as third groups for differentiation from the second groups of the above described embodiment.

In the groups, the partial volumes are in each case sorted according to which is in each case the largest with respect to the sorting criterion “positive semidefinite”. A starting volume Vⱼ is selected within a group. The starting volume may be selected randomly or also according to a criterion, for example the partial volume with the highest eigenvalue for the matrix.

For the starting volume Vⱼ, the difference between the matrix M_{Bj} and the matrix M_{B1} of another volume V₁ allocated to the same group is formed and checked as to whether the difference matrix is positive semidefinite.

If the difference matrix is positive semidefinite, a further partial volume of the group is selected that has not already been checked and then the difference between the matrix M_{Bj} and the matrix M_{B1} of this partial volume checked as to whether the difference matrix is positive semidefinite.

However, if the difference matrix is not positive semidefinite, the partial volume V₁ takes on the role as a new starting volume Vⱼ. The comparison is continued with the remaining partial volume of the respective third group until no partial volume remains that has not been compared with an another partial volume with respect to the sorting criterion as to whether the difference between the matrix M_{Bj} and the matrix M_{B1} is positive semidefinite. The last remaining partial volume that has taken on the role of the starting volume Vⱼ is then the maximum partial volume of the third group.

The sorting process is repeated within the other third groups until a maximum partial volume has been determined for each group.

The result is a quantity of highlighted partial volumes, one from each of the plurality of groups of partial volumes for which the condition applies that the magnitude of the magnetic field in this partial volume specifies a maximum for all partial volumes in the group for any activation signals.

The maximum function of the magnetic field magnitude |B| over all partial volumes is then indicated by the square root of the I^{T}*M_{Bj}*I for all groups. A maximum for the temporal change in the magnetic field magnitude may be determined in that, instead of the activation signal vectors I, the derivatives thereof with respect to time are multiplied by the matrix.

The respective activation signals may be multiplied by the matrices of the maximum partial volume determined and the absolute maximum of the magnetic field magnitude in all partial volumes to be determined during the operation of the magnetic resonance imaging scanner. The fact that the number of maximum partial volumes is significantly lower than the number of partial volumes enables the method to determine the magnetic field magnitude or the derivative thereof in real time.

In one embodiment, the number of partial volumes may be further reduced in that a tolerance limit epsilon ε is introduced that applies a safety margin to an upper bound for the magnetic field magnitude.

The criterion “positive semidefinite” is replaced by the criterion “epsilon positive semidefinite” with respect to the bound ε. As the bound increases the tolerance range, a larger number of partial volumes fulfills the condition and the groups of partial volumes are larger. The number of maximum partial volumes is reduced. Hence, the time for the calculation of the magnitude field magnitude maximum may be further reduced during the usage of the magnetic resonance imaging scanner.

Epsilon positive semidefinite is a matrix difference (M_{B1}−M_{Bj}) for a given positive value ε when all eigenvalues of the difference matrix (M_{B1}−M_{Bj}) are ≧−ε. For example, the matrix (M_{B1}−M_{Bj} ε*E) is then positive semidefinite, wherein the matrix E is the unit matrix with the same dimensions as M_{Bj}. Another suitable positive definite matrix is also conceivable instead of the unit matrix.

In one embodiment, the matrix M_{Bj} depends upon a weighting factor W specified to the computer by a user for a partial volume. It is, for example, conceivable for lower tolerance values to be permissible in certain partial volumes or, vice versa, for the object under examination to have higher sensitivity in this volume. Weighting the partial matrices with a corresponding weighting factor with a magnitude of greater than 1, enables the higher sensitivity to be taken into account since, to this end, the higher factor results in the determination of the exceeding of the limit value for lower activation signals.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionality as described herein.

A computer program (also known as a program, software, software application, script, or code) can be written in any form of programming language, including compiled or interpreted languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and anyone or more processors of any kind of digital computer. Generally, a processor receives instructions and data from a read only memory or a random access memory or both. The essential elements of a computer are a processor for performing instructions and one or more memory devices for storing instructions and data. Generally, a computer also includes, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio player, a Global Positioning System (GPS) receiver, to name just a few. Computer readable media suitable for storing computer program instructions and data include all forms of non-volatile memory, media and memory devices, including by way of example semiconductor memory devices, e.g., E PROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

Although the invention was illustrated and described in more detail by the embodiments, the invention is not restricted by the disclosed examples and other variations may be derived here from by the person skilled in the art without departing from the scope of protection of the invention.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A method for determining, for a magnetic resonance imaging scanner, a maximum function that indicates an upper bound of a magnetic field magnitude in an examination volume in dependence on a plurality of activation signals of magnetic coils acting on the examination volume, the examination volume divided into a plurality of partial volumes, the method comprising:
determining one or more first matrices that when multiplied by a vector formed from one or more activation signals of the plurality of activation signals, indicate a resultant square of the magnetic field magnitude |B|²=I^{T}*M_{B}*I for each partial volume of the plurality of partial volumes with the transposed vector (I^{T}) of vector (I).
grouping the plurality of partial volumes into a plurality of groups; and
determining a subscript index j for a first group of the plurality of groups so that, for a subscript index j of each other group of the plurality of groups, the difference between a matrix M_{Bj} and a matrix M_{B1} of each other element V₁ of the first group is epsilon positive semi definite, wherein the subscript index j characterizes a maximum partial volume;
wherein the maximum function of the magnetic field magnitude |B| is specified by the square root of the I^{T}*M_{Bj}*I of all groups.

2. The method of claim 1, further comprising:
determining a maximum temporal change in the magnetic field magnitude in a partial volume, wherein the first matrix is multiplied by the first derivative with respect to time of the vector (I) of the activation signals or the transposed vectors (I^{T}) thereof.

3. The method of claim 2, wherein grouping comprises:
selecting an initial partial volume that is not assigned to a group;
allocating the initial partial volume to a new second group; and
checking all other partial volumes (V₁) that have not yet been allocated to a group for whether the difference between the matrix M_{Bj} and the matrix M_{B1} is epsilon positive semidefinite with respect to a bound,
wherein the checked partial volume (V₁) that has not yet been assigned to a group is assigned to the second group if the difference between the matrix M_{Bj} and the matrix M_{B1} is epsilon positive semidefinite.

4. The method of claim 3, wherein the initial partial volume is selected as the initial partial volume the matrix M_{Bj} of which has a highest eigenvalue.

5. The method of claim 3, wherein the bound is derived from a highest eigenvalue for the initial partial volume.

6. The method of claim 3, wherein the bound is zero.

7. The method of claim 1, wherein grouping comprises:
selecting an initial partial volume that is not assigned to a group;
allocating the initial partial volume to a new second group; and
checking all other partial volumes (V₁) that have not yet been allocated to a group for whether the difference between the matrix M_{Bj} and the matrix M_{B1} is epsilon positive semidefinite with respect to a bound,
wherein the checked partial volume (V₁) that has not yet been assigned to a group is assigned to the second group if the difference between the matrix M_{Bj} and the matrix M_{B1} is epsilon positive semidefinite.

8. The method of claim 7, wherein the initial partial volume is selected as the initial partial volume the matrix M_{Bj} of that has a highest eigenvalue.

9. The method of claim 1, wherein grouping comprises:
selecting an initial partial volume of all partial volumes in a third group; and
checking all further partial volumes of the third group as to whether the difference between the matrix M_{Bj} and the matrix M_{B1} is epsilon positive semidefinite with respect to a bound,
wherein the checked partial volume becomes the new initial partial volume of the third group when the difference between the matrix M_{Bj} and the matrix M_{B1} is not epsilon positive semidefinite.

10. The method of claim 9, wherein the matrix M_{Bj} to be determined for the third group is determined on the basis of the matrix M_{Bj} specified for a respective initial partial volume (Vⱼ).

11. The method of claim 1, wherein the matrix M_{Bj} is determined using a weighting factor selected for the partial volume.

12. The method of claim 1, wherein grouping the partial volume of the examination volume into groups is a function of a grouping criterion.

13. An apparatus for determining for a magnetic resonance imaging scanner, a maximum function that indicates an upper bound of a magnetic field magnitude in an examination volume in dependence on a plurality of activation signals of magnetic coils acting on the examination volume, the examination volume divided into a plurality of partial volumes, the apparatus comprising:
at least one processor; and
at least one memory including computer program code for one or more programs; the at least one memory configured to store the computer program code configured to, with the at least one processor, cause the apparatus to at least perform:
determine one or more first matrices that when multiplied by a vector formed from one or more activation signals of the plurality of activation signals, indicate a resultant square of the magnetic field magnitude |B|²=I^{T}*M_{B}*I for each partial volume of the plurality of partial volumes with the transposed vector (I^{T}) of vector (I).
group the plurality of partial volumes into a plurality of groups; and
determine a subscript index j for a first group of the plurality of groups so that, for a subscript index j of each other group of the plurality of groups, the difference between a matrix M_{Bj} and a matrix M_{B1} of each other element V₁ of the first group is epsilon positive semi definite, wherein the subscript index j characterizes a maximum partial volume;
wherein the maximum function of the magnetic field magnitude |B| is specified by the square root of the I^{T}*M_{Bj}*I of all groups.

14. The apparatus of claim 13, wherein the at least one processor and at least one memory is configured to further cause the apparatus:
select an initial partial volume that is not assigned to a group;
allocate the initial partial volume to a new second group; and
check all other partial volumes (V₁) that have not yet been allocated to a group for whether the difference between the matrix M_{Bj} and the matrix M_{B1} is epsilon positive semidefinite with respect to a bound,
wherein the checked partial volume (V₁) that has not yet been assigned to a group is assigned to the second group if the difference between the matrix M_{Bj} and the matrix M_{B1} is epsilon positive semidefinite.

15. The apparatus of claim 14, wherein the initial partial volume is selected as the initial partial volume the matrix MBj of that has a highest eigenvalue.

16. The method of claim 14, wherein the bound is derived from a highest eigenvalue for the initial partial volume.

17. A magnetic resonance imaging scanner comprising:
a control system configured to determine a maximum change in a magnetic field in that a maximum value for the temporal derivative of the square root of I^{T}*M_{Bj}*I for a plurality of subscript index indices j of the maximum partial volume is determined, wherein the matrices M_{Bj} are determined by:
determining one or more first matrices that when multiplied by a vector formed from one or more activation signals of the plurality of activation signals, indicate a resultant square of the magnetic field magnitude |B|²=I^{T}*M_{B}*I for each partial volume of the plurality of partial volumes with the transposed vector (I^{T}) of vector (I).
grouping the plurality of partial volumes into a plurality of groups; and
determining a subscript index j for a first group of the plurality of groups so that, for the subscript index j of each other group of the plurality of groups, the difference between a matrix M_{Bj} and a matrix M_{B1} of each other element V₁ of the first group is epsilon positive semi definite, wherein the subscript index j characterizes a maximum partial volume;
wherein the maximum function of the magnetic field magnitude |B| is specified by the square root of the I^{T}*M_{Bj}*I of all groups.

18. The magnetic resonance imaging scanner of claim 17, wherein grouping comprises:
selecting an initial partial volume that is not assigned to a group;
allocating the initial partial volume to a new second group; and
checking all other partial volumes (V₁) that have not yet been allocated to a group for whether the difference between the matrix M_{Bj} and the matrix M_{B1} is epsilon positive semidefinite with respect to a bound,
wherein the checked partial volume (V₁) that has not yet been assigned to a group is assigned to the second group if the difference between the matrix M_{Bj} and the matrix M_{B1} is epsilon positive semidefinite

19. The magnetic resonance imaging scanner of claim 18, wherein the initial partial volume is selected as the initial partial volume the matrix MBj of that has a highest eigenvalue.

20. The magnetic resonance imaging scanner of claim 18, wherein the bound is derived from a highest eigenvalue for the initial partial volume
